(19) United States
(12) Patent Application Publication
(10) Pub. No.: US 2025/0287504 A1
(43) Pub. Date: Sep. 11, 2025

(54) Circuit Board

(71) Applicants: HONGFUJIN PRECISION INDUSTRY (WUHAN) CO., LTD., Wuhan City (CN); HON HAI PRECISION INDUSTRY CO., LTD., New Taipei City (TW)

(72) Inventors: Yumei Liu, Wuhan City (CN); Qi Cheng, Wuhan City (CN); Xirong Peng, Wuhan City (CN); Xiaoyan Yu, Wuhan City (CN); Chien Ling Liu, Wuhan City (CN)

(21) Appl. No.: 19/068,486

(22) Filed: Mar. 3, 2025

(30) Foreign Application Priority Data
Mar. 6, 2024 (CN) 2024102600672

(51) Int. Cl. H05K 1/14; H05K 1/18

(52) U.S. Cl. CPC H05K 1/142; H05K 1/181; H05K 2201/09063; H05K 2201/09227; H05K 2201/10159; H05K 2201/10189; H05K 2201/10325; H05K 2201/10522

(57) ABSTRACT

A circuit board includes a substrate, a processor socket, at least one dynamic random access memory socket, at least one peripheral component interconnect express socket, and a first connection socket. The first connection socket is provided on the substrate and is configured to electrically connect an extending circuit board. The circuit board is suitable for the first-type chassis specification. An assembly of the circuit board and the extending circuit board connected to each other and arranged on a same plane is suitable for a second-type chassis specification.

### FIELD

The disclosure relates to electrical connection devices, and more particularly, to a circuit board.

### BACKGROUND

Nowadays, personal computers with casings or chassis of various sizes provide different functions and meet different needs. Generally speaking, each size of chassis is designed with a dedicated motherboard (Mother Board), but this motherboard can only be used for this dedicated size of chassis, so that the developed motherboard can only be suitable for one or two sizes of chassis, resulting in higher development costs for motherboards. Because motherboards of the same size cannot be effectively applied to chassis of different sizes, the flexibility of motherboard use is affecting. Therefore, there is a need to solve the problems of manufacturing costs and usage flexibility of the above-mentioned motherboards.

### SUMMARY

In view of the above, the disclosure provides a circuit board to effectively solve the issue of manufacturing cost and usage flexibility in the prior art.

In order to achieve the above-mentioned object of the disclosure, one embodiment of the disclosure provides a circuit board including a substrate, a processor socket, at least one dynamic random access memory socket, at least one peripheral component interconnect express socket, and a first connection socket. The substrate includes a plurality of circuit layers and insulation layers. The processor socket is provided on the substrate. The at least one dynamic random access memory socket is provided on the substrate and is located on one side of the processor socket. The at least one peripheral component interconnect express socket is provided on the substrate and is located on another side of the processor socket. The peripheral component interconnect express socket is provided adjacent to the dynamic random access memory socket. The first connection socket is provided on the substrate and is configured to electrically connect with an extending circuit board. The circuit board is suitable for a first-type chassis specification. An assembly of the circuit board and the extending circuit board connected to each other and arranged on a same plane is suitable for a second-type chassis specification.

In one embodiment of the disclosure, the extending circuit board is provided with a second connection socket, and the second connection socket is used to electrically connect to the first connection socket of the circuit board.

In one embodiment of the disclosure, another peripheral component interconnect express socket is provided on the extending circuit board.

In one embodiment of the disclosure, the extending circuit board and the circuit board are assembled on the plane in a manner that a side of circuit board is joint with the extending circuit board or is apart from the extending circuit board with a preset distance.

In one embodiment of the disclosure, the substrate is provided with a first length and a first width, the first width of the substrate ranges from 215 mm to 222 mm, and the first length of the substrate ranges from 285 mm to 290 mm.

In one embodiment of the disclosure, the extending circuit board is provided with a second length and a second width, and the second length of the extending circuit board is less than or equal to the first length of the substrate.

In one embodiment of the disclosure, the substrate is provided with a protruding structure and reserved space for an external fan.

In one embodiment of the disclosure, the substrate is provided with a screw hole for fixing a processor heat sink, part of wiring of the processor socket provided on the substrate overlaps with a copper ring of the screw hole on the substrate.

In one embodiment of the disclosure, the substrate is provided with a screw hole for fixing a processor heat sink, and components around the screw hole are distributed to avoid the path through which part of wiring of the processor socket passes, and the components include guard holes around the screw hole.

In one embodiment of the disclosure, the circuit board further includes a platform controller hub provided on the substrate.

In one embodiment of the disclosure, the platform controller hub is provided at an intersection of an extension line of the peripheral component interconnect express socket and an extension line of the dynamic random access memory socket.

In one embodiment of the disclosure, a diameter of a copper ring of a via in the substrate for electrically connecting with a high-speed signal line of the platform controller hub at different layers is 20 mils, and the diameter of the via is 10 mils.

In one embodiment of the disclosure, the substrate includes 6 circuit layers.

In one embodiment of the disclosure, the circuit board further includes a solid-state disk socket provided on the substrate and located between the peripheral component interconnect express socket and the processor socket.

In one embodiment of the disclosure, the platform controller hub is provided between the peripheral component interconnect express socket and the processor socket.

In one embodiment of the disclosure, the substrate includes 4 circuit layers.

In one embodiment of the disclosure, the circuit board further includes at least two solid-state disk sockets provided on the substrate, and two groups of wiring of the platform controller hub respectively connected to the at least two solid-state disk sockets are spaced apart from each other on the substrate without overlapping.

In comparison with prior art, the circuit board of the disclosure is applied to a smaller personal computer chassis by the first connection socket configured to be electrically connected to the extending circuit board and can also be installed in a larger personal computer chassis by adding the extending circuit board and can also provide more functions through the extending circuit board. This provides a common circuit board for different sizes of personal computer chassis, improves flexibility, and effectively saves costs of design, molding and other manufacturing of the circuit board to avoid issues in the prior art.

### BRIEF DESCRIPTION OF DRAWINGS

FIG. 1 is a schematic top view of a structure of a circuit board according to one embodiment of the disclosure;

FIG. 2 illustrates a schematic front view of a structure of a circuit board according to one embodiment of the disclosure;

FIG. 3A is a schematic structural top view of a circuit board installed in a first-type chassis according to one embodiment of the disclosure;

FIG. 3B illustrates a schematic structural top view of a circuit board installed in a second-type chassis according to one embodiment of the disclosure;

FIG. 4 is a schematic structural diagram of a via according to an embodiment of the disclosure;

FIG. 5 is a schematic top view of the structure of a circuit board according to another embodiment of the disclosure;

FIG. 6 illustrates a schematic top view of a structure of a circuit board according to yet another embodiment of the disclosure;

FIG. 7 illustrates a schematic top view of a structure of a circuit board according to one embodiment of the disclosure;

FIG. 8 illustrates a schematic cross-sectional view of a structure of a screw hole according to an embodiment of the disclosure;

FIG. 9 is a schematic top view of a structure of a circuit board in the prior art.

FIG. 10 is a schematic cross-sectional view of a structure of a screw hole in the prior art.

Reference numerals description:
10, 10p: substrate; 100, 101, 101p, 102: circuit board; 11: protruding structure; 12, 12p: processor socket; 13, 131, 1311, 1311p, 1312, 1312p: solid-state disk socket; 14: dynamic random access memory socket; 16: peripheral component interconnect express socket; 18: first connection socket; 19, 19p: platform controller hub; 20: extending substrate; 200: extending circuit board; 26: peripheral component interconnect express socket; 28: second connection socket; BP: convex hull; CA1: first-type chassis; CA2: second-type chassis; CL, CLp: copper ring; D1, D2, D3, D4, D5: distance; E, E1: extension line; EF: external fan; GHp: guard hole; IL, IL1, IL1p, IL2, IL2p: insulation layer; IS: insulation pillar; L1, L2: length; S: plane; SH, SHp: screw hole; SSD: solid-state disk; TR1, TR1p, TR2, TR2p, TR3, TR3p, TR4, TR4p: wiring; VA: via; W1, W2: Width; X, Y, Z: coordinate axes

### DETAILED DESCRIPTION

In order to make the above and other objects, features, and advantages of the disclosure more obvious and understandable, preferred embodiments of the disclosure will be described below and explained in detail with reference to the drawings. Further, the directional terms mentioned in this disclosure, such as up, down, top, bottom, front, back, left, right, inside, outside, lateral, peripheral, central, horizontal, transverse, vertical, longitudinal, axial, radial, topmost or bottommost, etc., are only for reference to the direction of the drawings. Therefore, the directional terms described in the detailed description are used to illustrate and understand the disclosure, but not to limit the disclosure. In addition, in the drawings, structurally similar units are represented by the same reference numerals.

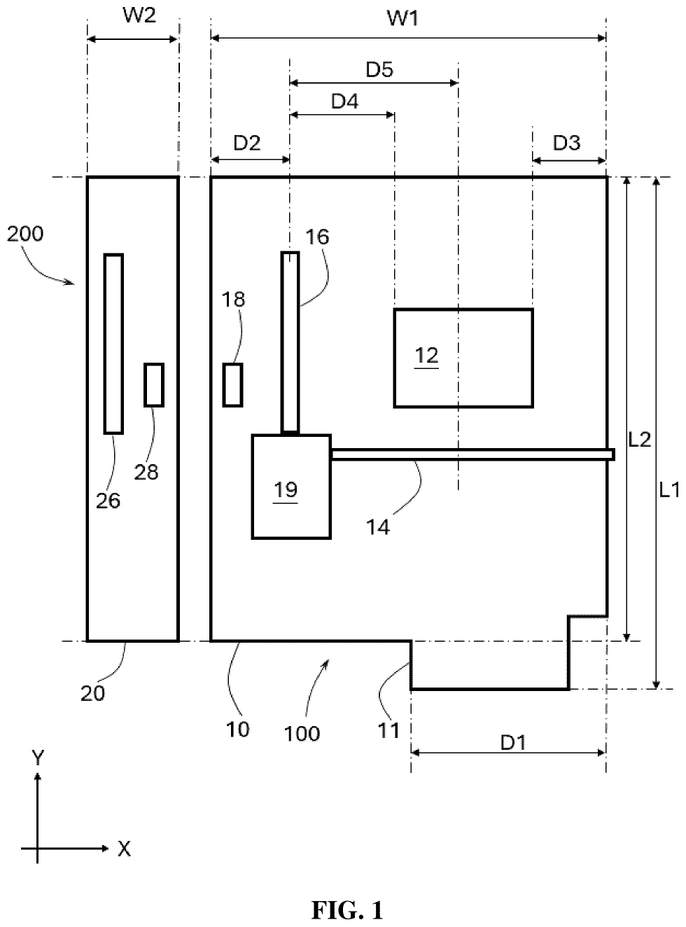

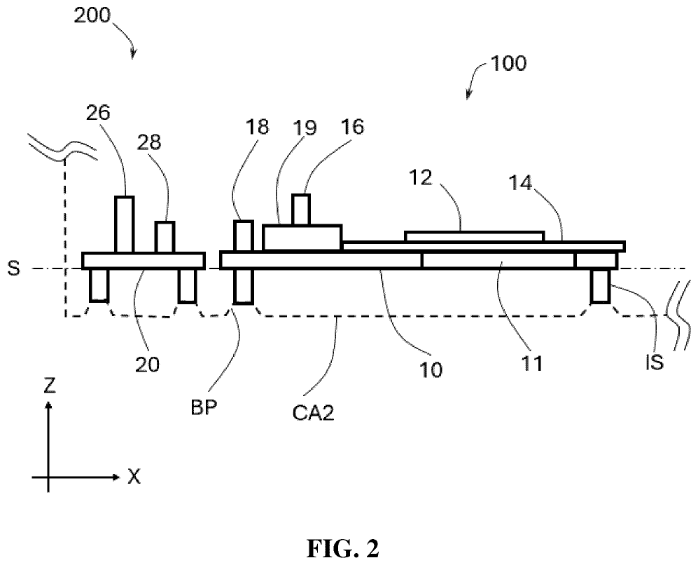

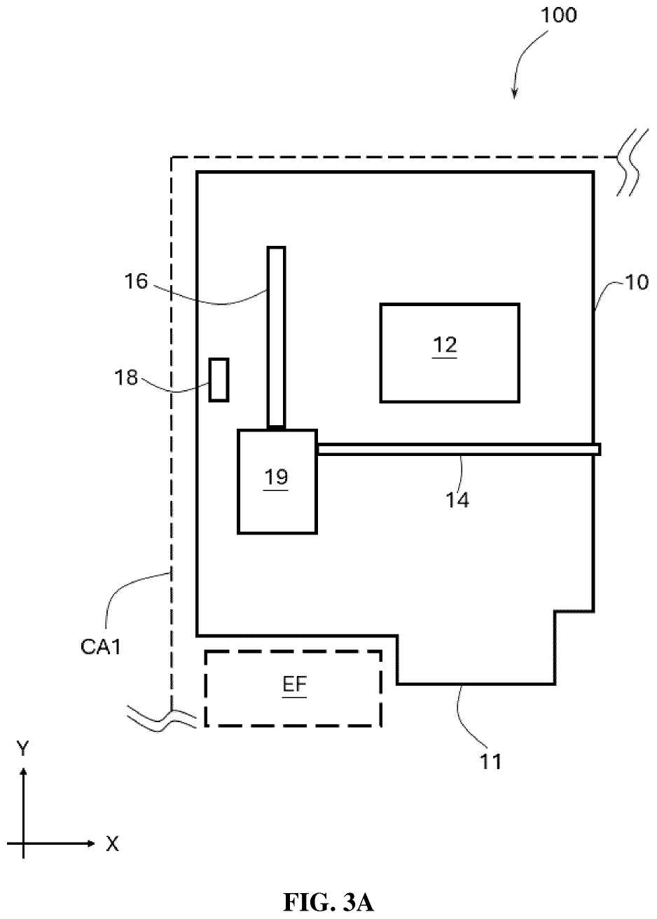

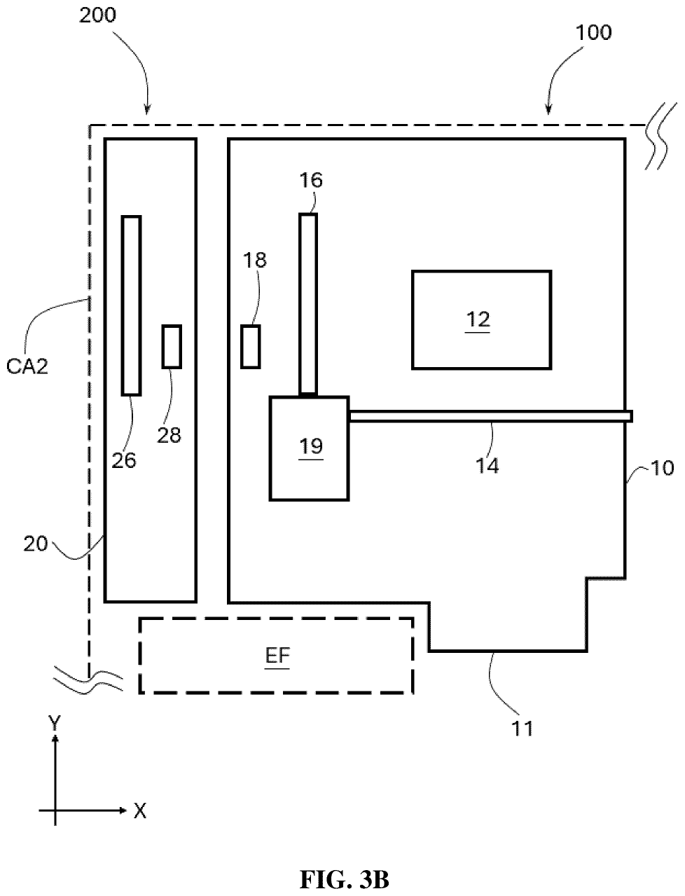

Referring to FIG. 1, FIG. 1 is a schematic top view of a structure of a circuit board according to an embodiment of the disclosure. The disclosure provides a circuit board 100 including: a substrate 10, a processor socket 12, at least one dynamic random access memory (DRAM) socket 14, at least one peripheral component interconnect express (PCI-E) socket 16, and a first connection socket 18. The substrate 10 includes a plurality of circuit layers and insulation layers. The processor socket 12 is provided on the substrate 10. The at least one DRAM socket 14 is provided on the substrate 10 and is located on one side of the processor socket 12. The at least one PCIE socket 16 is provided on the substrate 10 and is located on another side of the processor socket 12. The PCI-E socket 16 is provided adjacent to the DRAM socket 14. The first connection socket 18 is provided on the substrate 10 and configured to electrically connect to an extending circuit board 200. The circuit board 100 is suitable for a first-type chassis specification CA1 (refer to FIG. 3A). An assembly of the circuit board 100 and the extending circuit board 200 connected to each other and arranged on a same plane S (parallel to the XY plane, please refer to FIG. 2) is suitable for a second-type chassis specification CA2 (refer to FIG. 3B).

In detail, the substrate 10 is, for example, a multilayer composite circuit board. The processor socket 12 is, for example, a central processing unit (CPU) socket. The dynamic random access memory socket 14 is, for example, a dual in-line memory module (DIMM). The peripheral component interconnect express (PCI-E) socket 16 is, for example, a 1-channel (x1), 4-channel (x4), or 16-channel (x16) PCI-E socket.

Referring to FIG. 1, in an embodiment of the disclosure, the extending circuit board 200 includes an extending substrate 20. The extending substrate 20 is provided with a second connection socket 28. The second connection socket 28 is configured to electrically connect with the first connection socket 18 of the circuit board 100. The specific types and electrical connection methods of the second connection socket 28 and the first connection socket 18 are not limited. All protocols or transmission interfaces that can perform complete circuit signal transmission and reception between components provided on the extending circuit board 200 and the circuit board 100 are applicable. Another PCI-E socket 26 may be provided on the extending circuit board 200 to provide an additional transmission interface. For example, 1-channel (x1), 4-channel (x4), or 16-channel (x16) PCI-E socket may be additionally provided on the extending circuit board 200. Electronic components that can be provided on the extending circuit board 200 are not limited to this.

In detail, chassis sizes of personal computers can be classified from small to large, for example: small form factor (SFF), mini tower (MT), medium tower (MDT), and full tower (FT). In order to adapt a type of circuit board to multiple chassis sizes, such as the above-mentioned chassis sizes, the circuit board 100 must be small enough to be installed in a smaller chassis (e.g., SFF). However, in a larger chassis (e.g., MDT), in order to provide more components on the circuit board to perform more functions, the size of the circuit board (such as the motherboard) designed by the conventional technology is larger. The circuit board 100 of the disclosure is designed that can be installed in a smaller or larger chassis, that is, the circuit board 100 is installed in a smaller chassis (the first-type chassis CA1 shown in FIG. 3A), and both the circuit board 100 and the extending circuit board 200 can be installed together in a larger chassis (the second-type chassis CA2 shown in FIG. 3B). The circuit board 100 and the extending circuit board 200 can be connected through the first connection socket 18 and the second connection socket 28, so that the circuit board 100 can be configured with more components to include more functions through the extending circuit board 200.

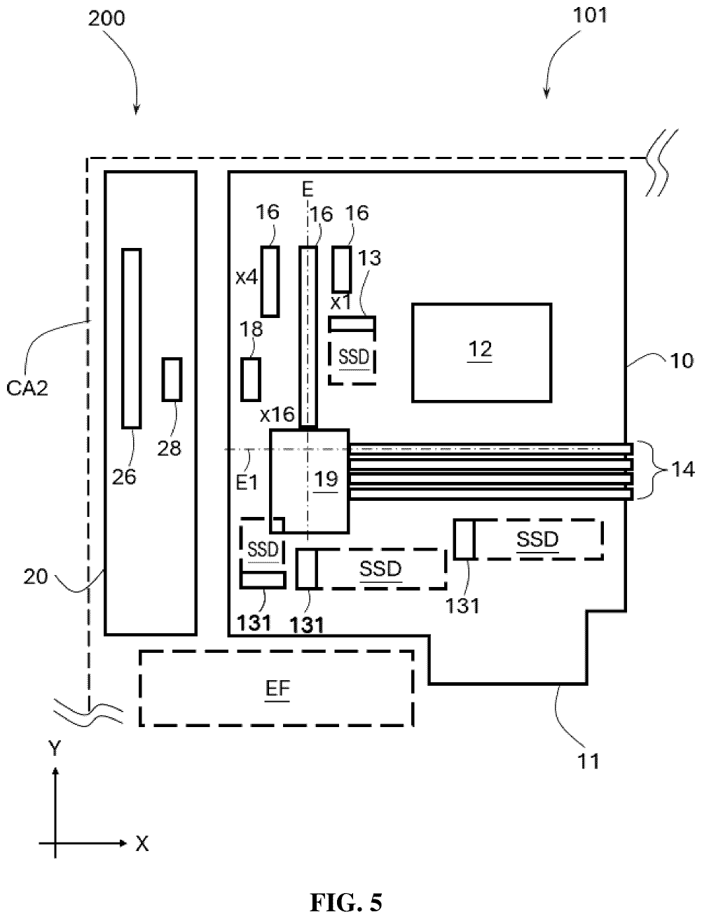

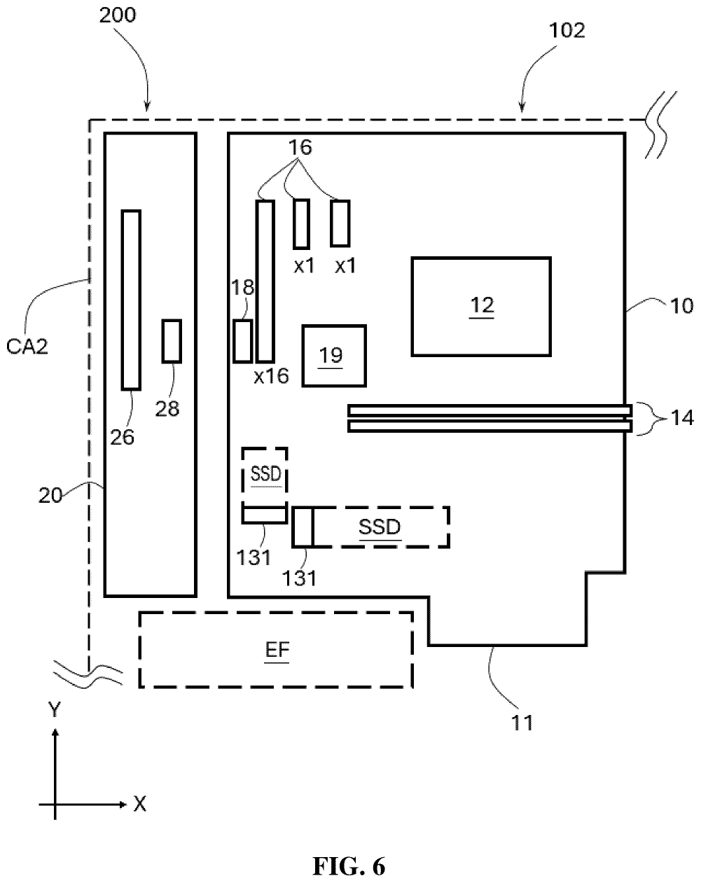

Referring to FIG. 1, in the embodiment of the disclosure, the substrate 10 is provided with a first length L1 in the Y direction and a first width W1 in the X direction. The extending circuit board 200 is provided with a second length L2 and a second width W2. The second width W2 is smaller than the first width W1. The first width W1 of the substrate 10 ranges from 215 mm to 222 mm. The first length L1 of the substrate 10 ranges from 285 mm to 290 mm. The second length L2 of the extending circuit board 200 is less than or equal to the first length L1 of the substrate 10, and ranges from 243 mm to 247 mm (corresponding to the circuit board 102 including 6 circuit layers in FIG. 5), or ranges from 244 mm to 247 mm (corresponding to circuit board 102 including 4 circuit layers in FIG. 6). In detail, for example, if the circuit board 100 is suitable for SFF, MT, MDT and FT chassis, the first length L1 of the substrate 10 remains unchanged, and ranges from 285 mm to 290 mm, so that the same circuit board packaging, such as a case/box, can be applied to improve the utilization rate of pallets for transporting circuit board products. The first width W1 is, for example, between 215 mm and 218 mm (corresponding to the circuit board 102 including 4 circuit layers in FIG. 6) or 219 mm to 222 mm (corresponding to the circuit board 102 including 6 circuit layers in FIG. 5), so that it can be installed in an SFF chassis. When the circuit board 100 and the extending circuit board 200 are electrically connected and arranged on the same plane S, they can be installed together in the chassis of the MT. In other examples, the circuit board 100 is suitable for MT, MDT and FT chassis sizes, then the first length L1 of the substrate 10 remains unchanged, and ranges from 285 mm to 290 mm (that is, the same when corresponding to the circuit board including 4 circuit layers in FIG. 6 or corresponding to the circuit board 102 including 6 circuit layers in FIG. 5), so that the same circuit board packaging, such as a case/box, can be used to improve the utilization rate of the pallet for transporting circuit board products.

Referring to FIG. 1, the distance D2 between the 16-channel (x16) PCI-E socket 16 and the substrate 10 is, for example, 43 mm to 46 mm, to maintain sufficient heat dissipation distance or heat discharge space between components (such as graphics cards) inserted in the PCI-E socket and components, such as system power supplies (power supply unit, PSU) in the SFF chassis. The distance D3 from edge of the processor socket 12 to edge of the substrate 10 is, for example, 39 mm to 43 mm (the same for the circuit board 102 containing 4 circuit layers in FIG. 6 or the circuit board 102 containing 6 circuit layers in FIG. 5), So that the circuit board 101 (refer to FIG. 5) and the circuit board 102 (refer to FIG. 6) can share a test fixture during a final test (FT) in the production process, effectively reducing the number of tests and test time, and reducing factory production cost. The distance D4 between the PCI-E socket 16 and the processor socket 12 is, for example, from 56 mm to 60 mm, so that the circuit board 100 can be reserved enough operating space for the fixtures and test fixtures for automated production in the factory during the final test (FT) in the production process. It also leaves space for the layout of other sockets (such as solid-state disk sockets) and high-frequency wiring layout space, the space required for a single wiring, the length of the wiring and the width of the power cable socket to facilitate layout of each hardware components. The distance D5 between the center of the platform controller hub (PCH) 19 and the center of the DRAM socket 14 is, for example, from 97 mm to 100 mm to reserve the space required for high-frequency wiring and single wiring. The distance from the center of the PCH 19 to the left edge of the substrate 10 is also D2, for example, from 43 mm to 46 mm, which is the space required for a high-frequency wiring layout and a single wiring.

Referring to FIG. 2, FIG. 2 is a schematic structural front view of a circuit board according to an embodiment of the disclosure. The extending circuit board 200 is suitable for being arranged on the same plane S (perpendicular to the Z axis) with the circuit board 100. For example, as shown in FIG. 2, the substrate 10 of the circuit board 100 and the extending substrate 20 of the extending circuit board 200 are arranged on the same plane S. The extending circuit board 200 and the circuit board 100 are assembled on the plane S in a manner that a side of circuit board 100 is joint with the extending circuit board 200 or is apart from the extending circuit board 200 with a preset distance. In detail, in order to install the circuit board 100 and the extending circuit board 200 in a larger chassis through the original mechanical components (such as the convex hull BP and the insulation pillar IS) of the chassis (the second-type chassis CA2 shown in FIG. 2), the circuit board 100 and the extending circuit board 200 are arranged on the same plane S to achieve the universality of the circuit board assembled by the circuit board 100 and the extending circuit board 200.

Referring to FIGS. 3A and 3B, a schematic top view of the structure of circuit boards installed in different chassis according to embodiments of the disclosure is shown. In the smaller first-type chassis CA1 of FIG. 3A, only the circuit board 100 is installed. In the larger second-type chassis CA2 in FIG. 3B, the circuit board 100 and the extending circuit board 200 are installed together. In one embodiment of the disclosure, the substrate 10 has a protruding structure 11 and reserves a space for arranging an external fan EF. In detail, the word “external” in the external fan EF means that the fan is not provided on the circuit board 100. So it is called an external fan. The external fan EF is generally arranged in a personal computer case, such as a system fan of a personal computer. In addition, in order to further reduce the size of the chassis and improve space utilization, the substrate 10 has a protruding structure 11 so that electronic components (not shown), such as sockets, can be provided on the protruding structure 11. The distance D1 from the left side to the right side of the protruding structure 11 at the lower edge of the substrate 10, for example, from 109 mm to 111 mm (corresponding to the circuit board 102 including 6 circuit layers in FIG. 5) or from 106 mm to 108 mm (corresponding to the circuit board 102 including 4 circuit layers in FIG. 6) is the optimal size reserving space for the arrangement of the external fan EF, so as to maximize the utilization of the panelization.

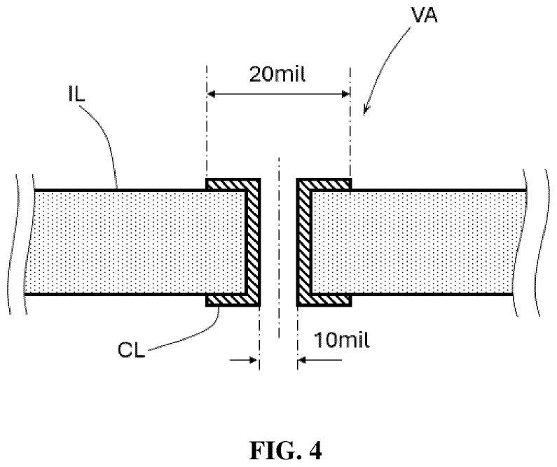

Continuing to refer to FIG. 1, in one embodiment of the disclosure, the circuit board 100 further includes a PCH 19 provided on the substrate 10. Referring to FIG. 3A and FIG. 4, FIG. 4 illustrates a structural schematic diagram of a via hole according to an embodiment of the disclosure. The diameter of the copper ring CL of the via VA in the substrate 10 for electrically connecting different layers of the high-speed signal line of the PCH 19 is 20 mil, and the diameter of the via hole is 10 mil. In detail, a via VA is provided in the insulation layer IL of the substrate 10, and a copper conductive layer (copper ring CL) is provided in the via VA so that the wiring of the high-speed signal line can change layers here. In order to install more electronic components on the circuit board 100 suitable for a smaller chassis, the via VA for changing layer of the high-speed signal line of the PCH 19 adopts a smaller size, for example, via20d10 specification, and the diameter of the copper ring CL is 20 mil and the diameter of the via VA is 10 mil.

Referring to FIG. 5, a schematic top view of the structure of a circuit board 101 according to another embodiment of the disclosure is shown. In one embodiment of the disclosure, the PCH 19 is provided at the intersection of the extension line E of the PCI-E socket 16 and the extension line E1 of the DRAM socket 14.

As shown in FIG. 5, in the embodiment of the disclosure, the circuit board 101 further includes a solid-state disk (SSD) socket 13 provided on the substrate 10 and located between the PCI-E socket 16 and the processor socket 12. In order to set up three PCI-E sockets 16 and set up a SSD socket 13 between the PCI-E socket 16 and the processor socket 12, PCI-E sockets 16 for 4 channels (x4), 16 channels (x16) and 1 channel (x1) are respectively provided along the X-axis direction (in FIG. 5) from the left to the right, so that there is space between PCI-E sockets 16 for 16 channels (x16) and the processor socket 12 for SSD socket 13 and SSD (indicated by a dotted line). In another embodiment, more SSD sockets 131 and DRAM sockets 14 can be provided in other spaces on the substrate 10.

In one embodiment of the disclosure, the substrate 10 includes six circuit layers stacked in the Z direction. Compared with the substrate 10 of the circuit board 102 (refer to FIG. 6) including 4 circuit layers, the circuit board 101 includes more circuit layers and has more wiring space, so that the circuit board 101 with 6 circuit layers can provided with more electronic components than the circuit board 102 including 4 circuit layers.

Referring to FIG. 6, a schematic top view of the structure of the circuit board 102 according to an embodiment of the disclosure is shown. In one embodiment of the disclosure, the PCH 19 is provided between the PCI-E socket 16 and the processor socket 12. In order to set up three PCI-E sockets 16 and set up a PCH 19 between the PCI-E socket 16 and the processor socket 12, PCI-E sockets 16 of 16 channels (x16), 1 channel (x1), and 1 channel (x1) are respectively set up along the X-axis direction from left to right in FIG. 6. So that there is space between the PCI-E sockets 16 of 16 channels (x16) and the processor sockets 12 to accommodate a PCH 19.

In one embodiment of the disclosure, the substrate 10 includes four circuit layers. In detail, the circuit board 102 with 4 circuit layers has fewer electronic components than that of the circuit board 101 with 6 circuit layers. However, in order to share the test fixtures in the production process, arrangements of the processor socket 12, DRAM socket 14, and x1 PCI-E socket 16 of the circuit board 102 and the circuit board 101 are the same in location. The distance of arrangements of other electronic components is slightly different. In detail, considering layout space for the high-frequency wiring structure and the space required for a single wiring, the distance from the left edge of the substrate 10 to the x16 PCI-E socket 16 ranges from 18 mm to 22 mm. The distance from the x16 PCI-E socket 16 to the center of the PCH 19 ranges from 38 mm to 42 mm, and the distance from the center of the PCH 19 to the edge of the heat sink of the processor socket 12 ranges from 38 mm to 42 mm. The distance from the center of the PCH 19 to the DRAM socket 14 ranges from 24 mm to 28 mm.

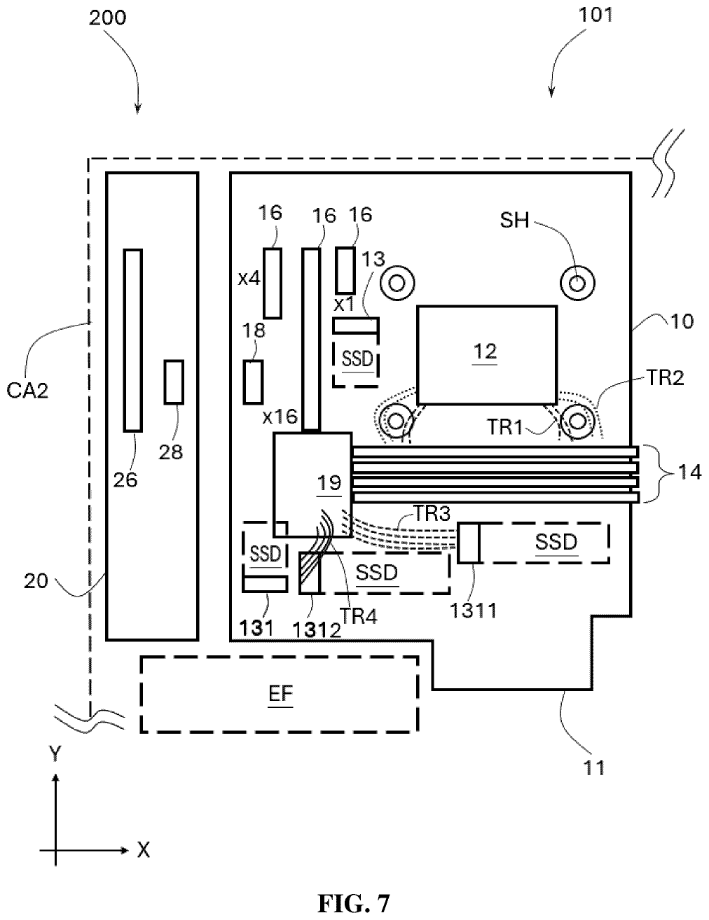

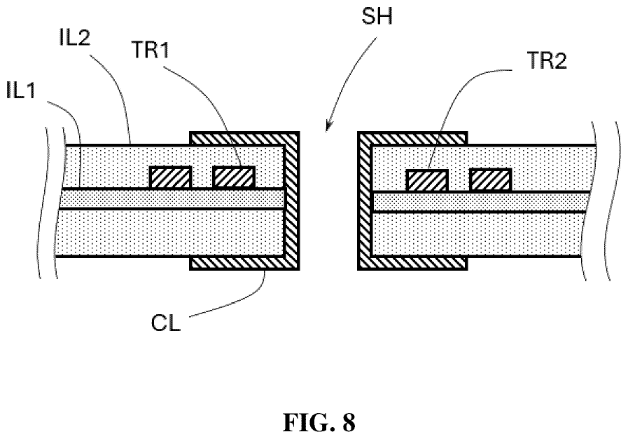

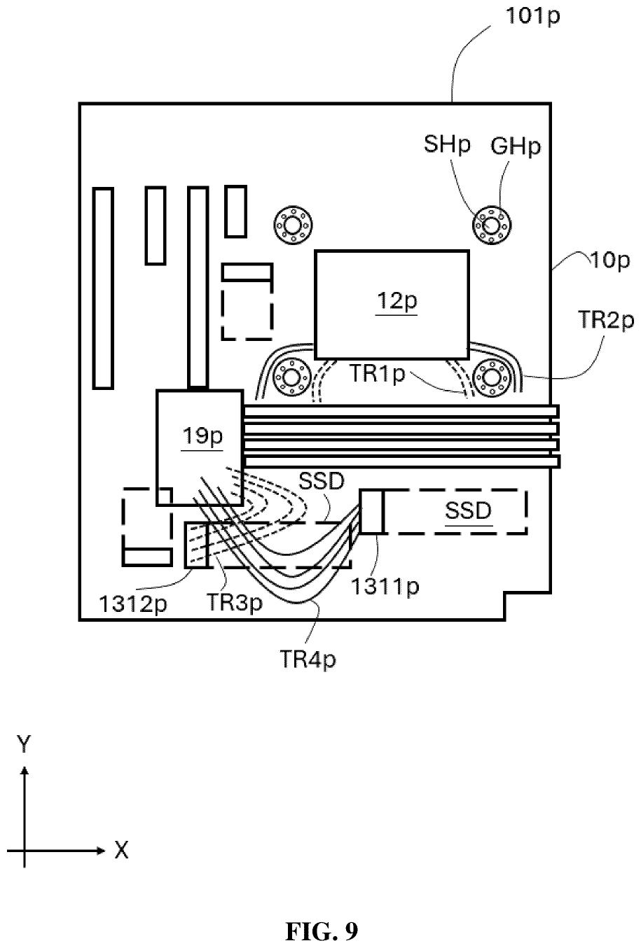

Referring to FIG. 7, a schematic top view of the structure of a circuit board according to one embodiment of the disclosure is shown. Referring to FIG. 8, a schematic cross-sectional view of the structure of a screw hole according to one embodiment of the disclosure is shown. In the embodiment of the circuit board 101 shown in FIG. 7, the substrate 10 is provided with a screw hole SH for fixing the processor heat sink. Part of the wiring TR1 of the processor socket 12 are overlapped to a copper ring CL of the screw hole SH on the substrate 10. In detail, an orthographic projection of part of the wiring TR1 of the processor socket 12 on the substrate 10 overlaps with an orthographic projection of the copper ring CL of the screw hole SH on the substrate 10. Furthermore, the distribution of components around the screw hole SH avoids the path through which some wiring TR1 of the processor socket 12 pass. For example, there is a guard hole setting area around the screw hole SH, which is used to set a plurality of guard holes GHp (refer to FIG. 9). The component distribution includes the distribution of the guard holes GHp around the screw hole SH. The distribution of the guard holes in the guard hole setting area avoids the path through which some wiring TR1 of the processor socket 12 pass. In another embodiment, there are no guard holes in the guard hole setting area around the screw hole SH that was originally used to set the guard hole GHp.

In detail, the substrate 10 includes, for example, a stacked first insulation layer IL1 and a second insulation layer IL2, as well as wiring TR1 and wiring TR2 provided on the first insulation layer IL1. The screw hole SH fixing the processor heat sink block is provided with a copper conductive layer (copper ring CL) extending from the second insulation layer IL2 into the screw hole SH to provide grounding. In order to match the size of the screw, the radius of the copper ring here is larger, and occupying the space of wiring TR1 and wiring TR2. However, guard holes may not be provided around the screw hole SH in this disclosure or there is an avoidance design of the guard holes. Therefore, the orthographic projection on the substrate 10 of some wiring TR1 or wiring TR2 of the processor socket 12 on different layers from the copper ring CL can be set to overlap with the orthographic projection on the substrate 10 of the copper ring CL of the screw hole SH. That is, space on the substrate 10 around the screw hole SH is available for wiring, so as to improve the space utilization, and reduce the size of the substrate 10. In one embodiment, the first width W1 of the substrate 10 can be reduced by 2 mm, so that the PCH 19 and the DRAM socket 14 can be closer. In other embodiments, the circuit board 100 and the circuit board 102 may also be adapted to the above-mentioned design of the screw holes SH, which will not be described again here.

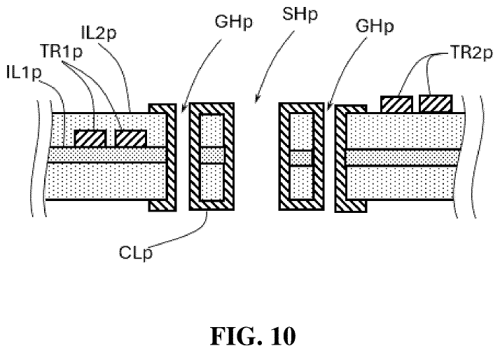

Referring to FIGS. 9 and 10, a guard hole GHp is provided next to a screw hole SHp of a heat sink on a substrate 10p of a conventional circuit board 101p, and its copper conductive layer CLp extends from the second insulation layer IL2p through the substrate 10p. Therefore, it not only occupies the routing space of the wiring TR2p of the processor socket 12p on the second insulation layer IL2p, but also occupies the routing space of the wiring TR1p of the processor socket 12p on the first insulation layer IL1p. It makes wiring space of configuration of the wiring and socket on the substrate 10p not compact enough, resulting in a large size of the substrate 10p or poor space utilization.

Referring to FIG. 7, the embodiment of the disclosure (e.g. the circuit board 101 in FIG. 7) further includes at least two SSD sockets 1311 and 1312 provided on the substrate 10, and two sets of wiring TR3 and TR4 of the PCH 19 respectively connecting the at least two SSD sockets 1311 and 1312 are separated from each other on the substrate 10 without overlapping to effectively reduce the wiring space and wiring length. In detail, the PCH 19 provides, for example, 2 to 3 sets of communication ports, such as M.2 interface sockets suitable for PCI-E signals, and each set of communication ports has 4 pins to provide high performance and large amount of output/input operations. In other words, the PCH 19 forms a direct connection with the at least two SSD sockets 1311 and 1312 in a non-interleaved manner using short wiring lengths to avoid excessive wiring occupying the substrate area. In one embodiment, as long as specifications of the two sets of communication ports of the PCH 19 support and are compatible with each other, the communication ports can be interchanged to achieve the effect of shortening the wiring and reducing the length of the substrate. In the prior art, the orthographic projections of two sets of wiring TR3p and TR4p that connect at least two SSD sockets 1311p and 1312p of the PCH 19p respectively overlap with each other on the substrate 10p (refer to FIG. 9). Even if the two sets of wiring TR3p and TR4p are located on different circuit layers, they still occupy a larger wiring space and require a longer trace length.

In comparison with prior art, the circuit board of the disclosure is applied to a smaller personal computer chassis by the first connection socket configured to be electrically connected to the extending circuit board and can also be installed in a larger personal computer chassis by adding the extending circuit board and can also provide more functions through the extending circuit board. This provides a common circuit board for different sizes of personal computer chassis, improves flexibility, and effectively saves costs of design, molding and other manufacturing of the circuit board to avoid issues in the prior art.

The above description is to illustrate the characteristics of the disclosure through preferred embodiments. The purpose is to enable those skilled in the art to understand the content of the disclosure and implement it accordingly, but not to limit the patent scope of the application. Therefore, any other equivalent modifications or modifications that do not depart from the technical ideas disclosed in this application shall still be included in the claim scope described below.

What is claimed is:

1. A circuit board, comprising:
a substrate, comprising a plurality of circuit layers and insulation layers;
a processor socket provided on the substrate;
at least one dynamic random access memory socket provided on the substrate and located on one side of the processor socket;
at least one peripheral component interconnect express socket provided on the substrate and located on another side of the processor socket, wherein the peripheral component interconnect express socket is provided adjacent to the dynamic random access memory socket; and
a first connection socket provided on the substrate and configured to electrically connect with an extending circuit board, wherein the circuit board is suitable for a first-type chassis specification, and an assembly of the circuit board and the extending circuit board connected to each other and arranged on a same plane is suitable for a second-type chassis specification.

2. The circuit board according to claim 1, wherein the extending circuit board is provided with a second connection socket, and the second connection socket is used to electrically connect to the first connection socket of the circuit board.

3. The circuit board according to claim 1, wherein another peripheral component interconnect express socket is provided on the extending circuit board.

4. The circuit board according to claim 1, wherein the extending circuit board and the circuit board are assembled on the plane in a manner that a side of circuit board is joint with the extending circuit board or is apart from the extending circuit board with a preset distance.

5. The circuit board according to claim 1, wherein the substrate is provided with a first length and a first width, the first width of the substrate ranges from 215 mm to 222 mm, and the first length of the substrate ranges from 285 mm to 290 mm.

6. The circuit board according to claim 5, wherein the extending circuit board is provided with a second length and a second width, and the second length of the extending circuit board is less than or equal to the first length of the substrate.

7. The circuit board according to claim 1, wherein the substrate is provided with a protruding structure and reserved space for an external fan.

8. The circuit board according to claim 1, wherein the substrate is provided with a screw hole for fixing a processor heat sink, part of wiring of the processor socket provided on the substrate overlaps with a copper ring of the screw hole on the substrate.

9. The circuit board according to claim 1, wherein the substrate is provided with a screw hole for fixing a processor heat sink, and components around the screw hole are distributed to avoid the path through which part of wiring of the processor socket passes, and the components include guard holes around the screw hole.

10. The circuit board according to claim 1, further comprising a platform controller hub provided on the substrate.

11. The circuit board according to claim 10, wherein the platform controller hub is provided at an intersection of an extension line of the peripheral component interconnect express socket and an extension line of the dynamic random access memory socket.

12. The circuit board according to claim 11, further comprising a solid-state disk socket provided on the substrate and located between the peripheral component interconnect express socket and the processor socket.

13. The circuit board according to claim 12, wherein the substrate includes six circuit layers.

14. The circuit board according to claim 10, wherein the platform controller hub is provided between the peripheral component interconnect express socket and the processor socket.

15. The circuit board according to claim 14, wherein the substrate includes four circuit layers.

16. The circuit board according to claim 10, wherein a diameter of a copper ring of a via in the substrate for electrically connecting with a high-speed signal line of the platform controller hub at different layers is 20 mils, and the diameter of the via is 10 mils.

17. The circuit board according to claim 10, further comprising at least two solid-state disk sockets provided on the substrate, and two groups of wiring of the platform controller hub respectively connected to the at least two solid-state disk sockets are spaced apart from each other on the substrate without overlapping.
